(19) United States
(12) Patent Application Publication
(10) Pub. No.: US 2024/0179885 A1
(43) Pub. Date: May 30, 2024

(54) METHOD OF FABRICATING SEMICONDUCTOR DEVICE

(71) Applicant: SEMES CO., LTD., Cheonan-si (KR)

(72) Inventors: Thomas Jongwan KWON, Gyeonggi-do (KR); Hae Won CHOI, Daejeon (KR); Yun Sang KIM, Gyeonggi-do (KR); Chengyeh HSU, Busan (KR)

(73) Assignee: SEMES CO., LTD., Cheonan-si (KR)

(21) Appl. No.: 18/495,266

(22) Filed: Oct. 26, 2023

(30) Foreign Application Priority Data
Nov. 24, 2022 (KR) 10-2022-0158935

(51) Int. Cl. H10B 12/00

(52) U.S. Cl. CPC H10B 12/053; H10B 12/09; H10B 12/34

(57) ABSTRACT

A method of fabricating a semiconductor device, which is capable of sufficiently filling trenches, is provided. The method includes: providing a substrate having defined thereon a plurality of active regions, which are spaced apart from one another by a device isolation film; forming a plurality of wordline trenches, which extend longitudinally in one direction, by removing portions of the active regions and portions of the device isolation film; forming gate insulating films along inner sidewalls of the wordline trenches; and forming wordlines, which fill portions of the wordline trenches, on the gate insulating films, wherein the forming the wordlines, comprises filling the portions of the wordline trenches with metal layers using a supercritical fluid deposition (SFD) method.

### CROSS-REFERENCE TO RELATED APPLICATION

This application claims priority from Korean Patent Application No. 10-2022-0158935 filed on Nov. 24, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a method of fabricating a semiconductor device.

### 2. Description of the Related Art

As semiconductor devices become highly integrated, individual circuit patterns are being further miniaturized to accommodate more semiconductor components within the same area. In other words, as the integration level of semiconductor devices increases, the design rules for their components are decreasing.

In highly scaled semiconductor devices, the process of filling trenches is becoming progressively challenging. As the size of the trenches reduces, filling the trenches with a metal through techniques such as atomic layer deposition (ALD) or chemical vapor deposition (CVD) leads to the occurrence of voids within the trenches due to an inadequate filling.

### SUMMARY

Aspects of the present disclosure provide a method of fabricating a semiconductor device, which can sufficiently fill trenches.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a method of fabricating a semiconductor device includes: providing a substrate having defined thereon a plurality of active regions, which are spaced apart from one another by a device isolation film; forming a plurality of wordline trenches, which extend longitudinally in one direction, by removing portions of the active regions and portions of the device isolation film; forming gate insulating films along inner sidewalls of the wordline trenches; and forming wordlines, which fill portions of the wordline trenches, on the gate insulating films, wherein the forming the wordlines, comprises filling the portions of the wordline trenches with metal layers using a supercritical fluid deposition (SFD) method.

According to another aspect of the present disclosure, a method of fabricating a semiconductor device includes: providing a substrate having defined thereon a plurality of active regions, which are spaced apart from one another by a device isolation film; forming a plurality of wordline trenches, which extend longitudinally in one direction, by removing portions of the active regions and portions of the device isolation film; forming gate insulating films along inner sidewalls of the wordline trenches; and forming wordlines, which fill portions of the wordline trenches, on the gate insulating films, wherein the forming the wordlines, comprises placing the substrate with the wordline trenches formed therein within a reactor, supplying a metal precursor and carbon dioxide into the reactor such that the metal precursor penetrates into the wordline trenches, and supplying a reduction gas into the reactor such that a metal of the metal precursor is deposited within the wordline trenches, the metal precursor and the carbon dioxide are in a supercritical state within the reactor, the metal of the metal precursor is at least one of Ru, Mo, Cu, and TiN, a ligand of the metal precursor consists of one of Cₓ, H_{y}, and CₓH_{y} (where x and y are natural numbers), the reduction gas is in a supercritical state within the reactor, and the forming the wordlines, comprises forming pre-metal layers, which completely fill the wordline trenches, by repeating both the supplying the metal precursor and the carbon dioxide into the reactor and the supplying the reduction gas into the reactor multiple times, and forming metal layers, which fill the portions of the wordline trenches, by removing portions of the pre-metal layers using an atomic layer etching (ALE) method.

According to another aspect of the present disclosure, a method of fabricating a semiconductor device includes: providing a substrate, which includes a cell region and a peripheral region defined around the cell region; and forming first transistors in the cell region and second transistors in the peripheral region, the first transistors and the second transistors being buried channel array transistors (BCATs), wherein the forming the first transistors and the second transistors, comprises forming first trenches in the cell region and second trenches in the peripheral region, forming first gate insulating films along inner sidewalls of the first trenches and second gate insulating films along inner sidewalls of the second trenches, and filling portions of the first trenches with first metal layers and portions of the second trenches with second metal layers by forming the first metal layers on the first gate insulating films and the second metal layers on the second gate insulating films using an SFD method.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic layout view of a semiconductor device according to some embodiments of the present disclosure;

FIG. 2 is a schematic layout view illustrating a cell region of FIG. 1;

FIG. 3 is a layout view illustrating wordlines and active regions of FIG. 2;

FIG. 4 is a cross-sectional view taken along line A-A of FIG. 2;

FIG. 5 is a cross-sectional view taken along line B-B of FIG. 2;

FIG. 6 is a flowchart illustrating a method of fabricating a semiconductor device according to some embodiments of the present disclosure;

FIG. 7 is a cross-sectional view illustrating S310 of FIG. 6;

FIG. 8 is a cross-sectional view illustrating S320 of FIG. 6;

FIG. 9 is a cross-sectional view illustrating S330 of FIG. 6;

FIG. 10 is a schematic view illustrating semiconductor manufacturing equipment for performing S340 of FIG. 6;

FIG. 11 is a schematic view illustrating an exemplary operating method of the semiconductor manufacturing equipment of FIG. 10;

FIG. 12 is a schematic view illustrating another exemplary operating method of the semiconductor manufacturing equipment of FIG. 10;

FIG. 13 illustrates cross-sectional views illustrating S340 of FIG. 6; and

FIG. 14 is a cross-sectional view illustrating the formation of metal layers (or wordlines) after S346 of FIG. 13.

### DETAILED DESCRIPTION

Embodiments of the present disclosure will be described with reference to the attached drawings. The same reference numerals are used for the same components in the drawings, and redundant descriptions for these components will be omitted.

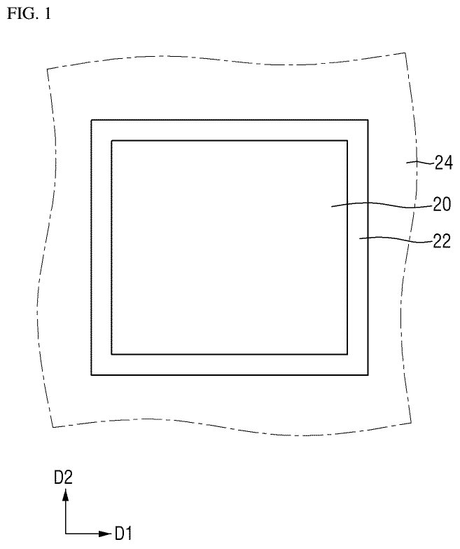

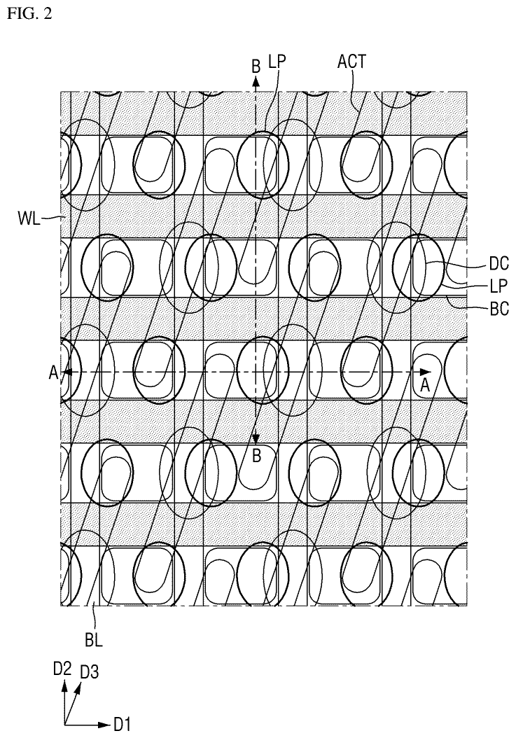

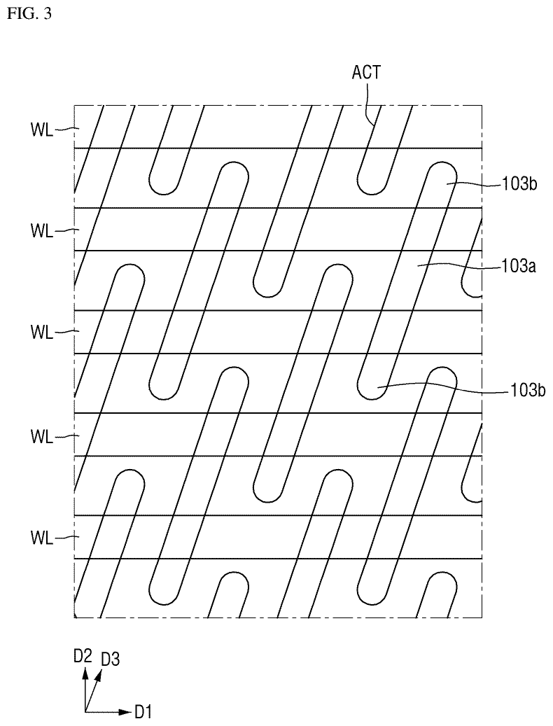

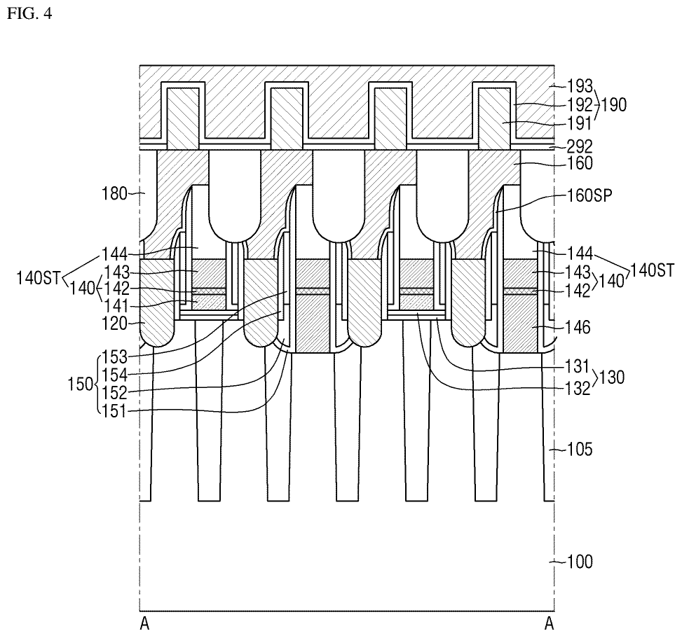

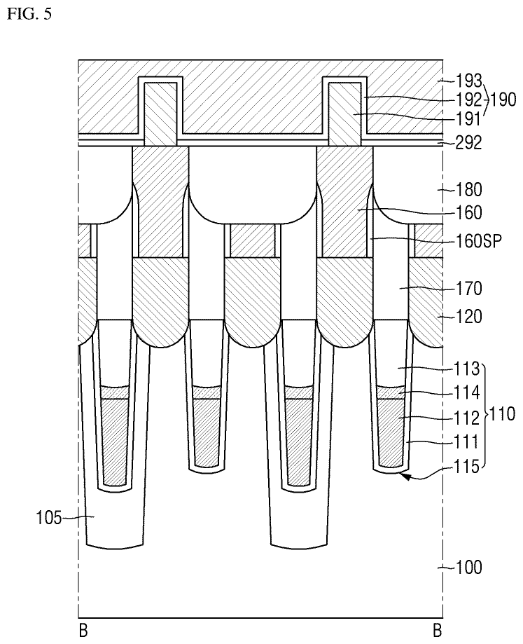

FIG. 1 is a schematic layout view of a semiconductor device according to some embodiments of the present disclosure. FIG. 2 is a schematic layout view illustrating a cell region of FIG. 1. FIG. 3 is a layout view illustrating wordlines and active regions of FIG. 2. FIG. 4 is a cross-sectional view taken along line A-A of FIG. 2. FIG. 5 is a cross-sectional view taken along line B-B of FIG. 2.

The semiconductor device according to some embodiments of the present disclosure is illustrated as being, for example, a dynamic random access memory (DRAM), but the present disclosure is not limited thereto.

Referring to FIGS. 1 through 3, the semiconductor device according to some embodiments of the present disclosure may include a cell region 20, a region isolation film 22, and a peripheral region 24.

The region isolation film 22 may be formed along the circumference of the cell region 20, but the present disclosure is not limited thereto. The region isolation film 22 may separate the cell region 20 and the peripheral region 24. The peripheral region 24 may be defined around the cell region 20.

The cell isolation region 22 may include a plurality of active regions ACT. The active regions ACT may be defined by a device isolation film (“105” of FIG. 4), which is formed within a substrate (“100” of FIG. 4). As the design rule for the semiconductor device according to some embodiments of the present disclosure decreases, the active regions ACT may be arranged as bars such as diagonal or oblique bars. For example, the active regions ACT may extend in a third direction D3.

A plurality of gate electrodes, which extend in a first direction D1, may be arranged across the active regions ACT. The gate electrodes may extend in parallel to one another. The gate electrodes may be, for example, wordlines WL. The wordlines WL may be arranged at equal intervals. The width of the wordlines WL or the spacing between the wordlines WL may be determined based on the design rule for the semiconductor device according to some embodiments of the present disclosure.

Each of the active regions ACT may be divided into three sections, i.e., two storage connection regions 103b and a bitline connection region 103a, by two adjacent wordlines WL extending in the first direction D1. The bitline connection region 103a may be positioned in the middle of the corresponding active region ACT, and the storage connection regions 103b may be positioned at either end of the corresponding region ACT.

A plurality of bitlines BL, which extend in a second direction D2 intersecting with the first direction D1, may be disposed on the wordlines WL. The bitlines BL may extend in parallel to one another. The bitlines BL may be arranged at equal intervals. The width of the bitlines BL or the spacing between the bitlines BL may be determined based on the design rule for the semiconductor device according to some embodiments of the present disclosure.

The semiconductor device according to some embodiments of the present disclosure may include various contact arrays, which are formed on the active regions ACT. The contact arrays may include, for example, direct contacts DC, buried contacts BC, and landing pads LP.

Here, the direct contacts DC may refer to contacts that electrically connect the active regions ACT to the bitlines BL. The buried contacts BC may refer to contacts that connect the active regions ACT to lower electrodes (“191” of FIG. 4) of capacitors. The contact area between the buried contacts BC and the active regions ACT may be small. Consequently, to increase the contact area with the active regions ACT and expand the contact area with the lower electrodes 191, the landing pads LP, which have conductivity, may be introduced.

The landing pads LP may be positioned between the active regions ACT and the buried contacts BC, or between the buried contacts BC and the lower electrodes 191. The landing pads LP may be positioned between the buried contacts BC and the lower electrodes 191. By increasing the contact area with the active regions ACT and with the lower electrodes 191 via the landing pads LP, the contact resistance between the active regions ACT and the electrodes 191 can be reduced.

The direct contacts DC may be connected to the bitline connection regions 103a of the active regions ACT. The buried contacts BC may be connected to the storage connection regions 103b of the active regions ACT. As the buried contacts BC are disposed at their respective ends of the active regions ACT, the landing pads LP may be disposed to partially overlap with the buried contacts BC near their respective ends of the active regions ACT. In other words, the buried contacts BC may be disposed to overlap with the active regions ACT and the device isolation film 105 between the wordlines WL, which are adjacent to one another, and between the bitlines BL, which are adjacent to one another.

The wordlines WL may be formed to be buried in the substrate 100. The wordlines WL may be arranged across the active regions ACT between the direct contacts DC or the buried contacts BC. Two wordlines WL may be arranged across one cell active region ACT. As the active regions ACT extend in the third direction D3, the wordlines WL may form an angle smaller than 90 degrees with the active regions ACT.

The direct contacts DC and the buried contacts BC may symmetrically arranged. As a result, the direct contacts DC and the buried contacts BC may be arranged in rows along the first and second directions D1 and D2. The landing pads LP, unlike the direct contacts DC and the buried contacts BC, may be arranged in a zigzag pattern in the second direction D2, which corresponds to the extension direction of the bitlines BL. The landing pads LP may be positioned to overlap with the same side surface of their respective bitlines BL in the first direction D1, which corresponds to the extension direction of the wordlines WL. For example, landing pads LP in a first row may overlap with the left side surfaces of their corresponding bitlines BL, and landing pads LP in a second row may overlap with the right side surfaces of their corresponding bitlines BL.

Referring to FIGS. 1 through 5, the semiconductor device according to some embodiments of the present disclosure may include a plurality of gate structures 110, a plurality of bitline structures 140ST, a plurality of storage contacts 120, and an information storage section 190.

The substrate 100 may include the cell region 20, the region isolation film 22, and the peripheral region 24. The substrate 100 may be a silicon substrate or a silicon-on-insulator (SOI) substrate. Alternatively, the substrate 100 may include silicon germanium, silicon germanium-on-insulator (SGOI), indium antimonide, lead tellurium compound, indium arsenide, indium phosphide, gallium arsenide, or gallium antimonide, but the present disclosure is not limited thereto.

The gate structures 110, the bitline structures 140ST, the storage contacts 120, and the information storage section 190 may be disposed in the cell region 20. Although not explicitly illustrated, a peripheral gate structure may be disposed in the peripheral region.

The device isolation film 105 may be formed in the cell region 20 of the substrate 100. The device isolation film 105 may have a shallow trench isolation (STI) structure with excellent device isolation characteristics. The device isolation film 105 may define the active regions ACT in the cell region 20. The active regions ACT, which are defined by the device isolation film 105, may have a long island shape with short and long axes, as illustrated in FIG. 2. The active regions ACT may have a diagonal line shape, forming an angle smaller than 90 degrees with the wordlines WL, which are formed within the device isolation film 105. Also, the active regions ACT may have a diagonal line shape, forming an angle smaller than 90 degrees with the bitlines BL, which are formed on the device isolation film 105.

A cell boundary isolation film with an STI structure may be formed as the region isolation film 22. The cell region 20 may be defined by the region isolation film 22.

The device isolation film 105 and the region isolation film 22 may include at least one of, for example, silicon oxide, silicon nitride, and silicon oxynitride, but the present disclosure is not limited thereto. FIGS. 4 and 5 illustrate that the device isolation film 105 and the region isolation film 22 are formed as single insulating films, but the present disclosure is not limited thereto. The device isolation film 105 and the region isolation film 22 may be formed as single insulating films or as multiple insulating films depending on their respective widths.

The gate structures 110 may be formed within the substrate 100 and the device isolation film 105. The gate structures 110 may be formed across the device isolation film 105 and the active regions ACT, which are defined by the device isolation film 105. The gate structures 110 may include gate trenches 115, which are formed within the substrate 100 and the device isolation film 105, gate insulating films 111, gate electrodes 112, capping insulating films 113, and capping conductive films 114. Here, the gate electrodes 112 may correspond to the wordlines WL. Thus, the gate trenches 115 may also be referred to as wordline trenches, the capping insulating films 113 may also be referred to as cell gate capping insulating films, and the capping conductive films 114 may also be referred to as cell gate capping conductive films. Unlike what is depicted, the gate structures 110 may not include the capping conductive films 114.

The gate insulating films 111 may extend along the sidewalls and bottom surfaces (i.e., the inner sidewalls) of the gate trenches 115. The gate insulating films 111 may extend along at least some of the profiles of the gate trenches 115. The gate insulating films 111 may include at least one of, for example, silicon oxide, silicon nitride, silicon oxynitride, or a high-k material with a greater dielectric constant than silicon oxide. The high-k material may include at least one of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof.

The gate electrodes (or wordlines) 112 may be formed on the gate insulating films 111. The gate electrodes 112 may fill portions of the gate trenches 115. The capping conductive films 114 may extend along the top surfaces of the gate electrodes 112, but the present disclosure is not limited thereto.

The gate electrodes 112 may include at least one of a metal, a metal alloy, a conductive metal nitride, a conductive metal carbonitride, a conductive metal carbide, a metal silicide, a conductive metal oxynitride, and a conductive metal oxide. The gate electrodes 112 may include at least one of, for example, TiN, TaC, TaN, TiSiN, TaSiN, TaTiN, TiAlN, TaAlN, WN, Ru, TiAl, TiAlC—N, TiAlC, TIC, TaCN, W, Al, Cu, Co, Ti, Ta, Ni, Pt, Ni—Pt, Nb, NbN, NbC, Mo, MON, MoC, WC, Rh, Pd, Ir, Ag, Au, Zn, V, RuTiN, TiSi, TaSi, NiSi, CoSi, IrOₓ, RuOₓ, and a combination thereof, but the present disclosure is not limited thereto. The capping conductive films 114 may include, for example, polysilicon or polysilicon germanium, but the present disclosure is not limited thereto.

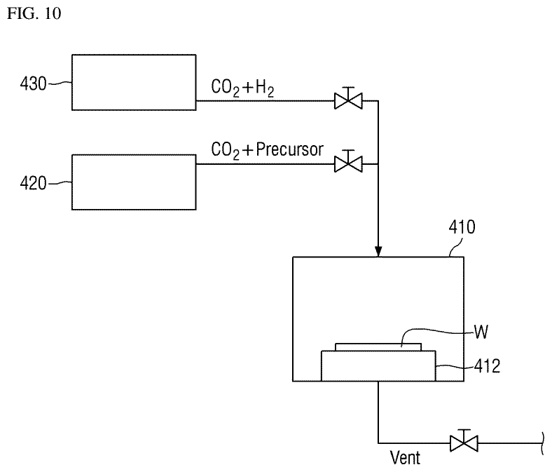

In some embodiments, the gate electrodes 112 may be formed by a supercritical fluid sequential fill (SFSF) method or a supercritical fluid deposition (SFD) method. This will be described later with reference to FIGS. 10 through 14.

The capping insulating films 113 may be disposed on the gate electrodes 112 and the capping conductive films 114. The capping insulating films 113 may fill portions of the gate trenches 115 that remain empty after the formation of the gate electrodes 112 and the capping conductive films 114. The gate insulating films 111 may extend along the sidewalls of the capping insulating films 113, but the present disclosure is not limited thereto. The capping insulating films 113 may include at least one of, for example, silicon nitride (SiN), silicon oxynitride (SiON), silicon oxide (SiO₂), silicon carbonitride (SiCN), silicon oxycarbonitride (SiOCN), and a combination thereof.

Although not explicitly illustrated, impurity-doped regions may be formed on at least one side of each of the gate structures 110. The impurity-doped regions may be source/drain regions of transistors.

Meanwhile, referring to FIG. 4, the bitline structures 140ST may include cell conductive lines 140 and cell line capping films 144. The cell conductive lines 140 may be formed on the substrate 100 and the device isolation film 105 where the gate structures 110 are formed. The cell conductive lines 140 may intersect with the device isolation film 105, and the active regions ACT, which are defined by the device isolation film 105. The cell conductive lines 140 may be formed to intersect with the gate structures 110. Here, the cell conductive lines 140 may correspond to the bitlines BL.

The cell conductive lines 140 may be multifilms. The cell conductive lines 140 may include, for example, first cell conductive films 141, second cell conductive films 142, and third cell conductive films 143. The first cell conductive films 141, the second cell conductive films 142, and the third cell conductive films 143 may be sequentially stacked on the substrate 100 and the device isolation film 105. The cell conductive lines 140 may be triple films, but the present disclosure is not limited thereto.

The first cell conductive films 141, the second cell conductive films 142, and the third cell conductive films 143 may include at least one of, for example, an impurity-doped semiconductor material, a conductive silicide compound, a conductive metal nitride metal, and a metal alloy. For example, the first cell conductive films 141 may include a doped semiconductor material, the second cell conductive films 142 may include at least one of a conductive silicide compound and a conductive metal nitride, and the third cell conductive films 143 may include at least one of a metal and a metal alloy. However, the present disclosure is not limited to this example.

Bitline contacts 146 may be formed between the cell conductive lines 140 and the substrate 100. That is, the cell conductive lines 140 may be formed on the bitline contacts 146. For example, the bitline contacts 146 may be formed at the intersections between the cell conductive lines 140 and the middle portions of the active regions ACT, which have a long island shape. The bitline contacts 146 may be formed between the cell conductive lines 140 and the bitline connection regions 103a of the active regions ACT.

The bitline contacts 146 may electrically connect the cell conductive lines 140 and the substrate 100. In this case, the bitline contacts 146 may correspond to the direct contacts DC. The bitline contacts 146 may include at least one of, for example, an impurity-doped semiconductor material, a conductive silicide compound, a conductive metal nitride, and a metal.

As depicted in FIG. 4, within the overlapping areas of the cell conductive lines 140 and the top surfaces of the bitline contacts 146, the cell conductive lines 140 may include the second cell conductive films 142 and the third cell conductive films 143. In contrast, in the non-overlapping areas of the cell conductive lines 140 and the top surfaces of the bitline contacts 146, the cell conductive lines 140 may include the first cell conductive films 141, the second cell conductive films 142, and the third cell conductive films 143.

The cell line capping films 144 may be disposed on the cell conductive lines 140. The cell line capping films 144 may extend along the top surfaces of the cell conductive lines 140 in the second direction D2. In this case, the cell line capping films 144 may include at least one of, for example, SiN, SiON, silicon carbide (SiC), and silicon oxycarbide (SiOC). In some embodiments, the cell line capping films 144 may include, for example, silicon nitride. The cell line capping films 144 are illustrated as being single films, but the present disclosure is not limited thereto. Alternatively, the cell line capping films 144 may be multifilms. However, if each of the cell line capping films 144 includes multiple films formed of the same material, each of the cell line capping films 144 may appear as single films.

The cell insulating films 130 may be formed on the substrate 100 and the device isolation film 105. Specifically, the cell insulating films 130 may be formed on the substrate 100 and the device isolation film 105 where bitline contacts 146 are not formed. The cell insulating films 130 may be formed between the substrate 100 and the cell conductive lines 140, as well as between the device isolation film 105 and the cell conductive lines 140.

The cell insulating layers 130 may be a single film, but may also be a multifilm including first cell insulating films 131 and second cell insulating films 132. For example, the first cell insulating films 131 may include SiO₂, and the second cell insulating films 132 may include SiN. However, the present disclosure is not limited to this example.

Cell line spacers 150 may be disposed on the sidewalls of the cell conductive lines 140 and the cell line capping films 144. The cell line spacers 150 may be formed on the substrate 100 and on the device isolation film 105, on portions of the cell conductive lines 140 where the bitline contacts 146 are formed. The cell line spacers 150 may also be disposed on the sidewalls of the cell conductive lines 140, the cell line capping films 144, and the bitline contacts 146.

However, the cell line spacers 150 may be disposed on the cell insulating films 130, on other portions of the cell conductive lines 140 where bitline contacts 146 are not formed. The cell line spacers 150 may be disposed on the sidewalls of the cell conductive lines 140 and the cell line capping films 144.

The cell line spacers 150 may be single films, but may also be multifilms including first cell line spacers 151, second cell line spacers 152, third cell line spacers 153, and fourth cell line spacers 154. For example, the first cell line spacers 151, the second cell line spacers 152, the third cell line spacers 153, and the fourth cell line spacers 154 may include SiO₂, SiN, SiON, SiOCN, air, and a combination thereof, but the present disclosure is not limited thereto.

Fence patterns 170 may be disposed on the substrate 100 and the device isolation film 105. The fence patterns 170 may be formed to overlap with the gate structures 110, which are formed within the substrate 100 and the device isolation film 105. The fence patterns 170 may be disposed between bitline structures 140ST extending in the second direction D2. The fence patterns 170 may include at least one of, for example, SiO₂, SiN, SiON, and a combination thereof.

Storage contacts 120 may be disposed between adjacent cell conductive lines 140 in the first direction D1. The storage contacts 120 may be positioned between adjacent fence patterns 170 in the second direction D2. The storage contacts 120 may overlap with the substrate 100 and the device isolation film 105 between the adjacent cell conductive lines 140 in the first direction D1. The storage contacts 120 may be connected to the storage connection regions 103b of the active regions ACT. Here, the storage contacts 120 may correspond to the buried contacts BC.

The storage contacts 120 may include at least one of, for example, an impurity-doped semiconductor material, a conductive silicide compound, a conductive metal nitride, and a metal.

Storage pads 160 may be formed on the storage contacts 120. The storage pads 160 may be electrically connected to the storage contacts 120. Here, the storage pads 160 may correspond to the landing pads LP.

The storage pads 160 may partially overlap with the top surfaces of the bitline structures 140ST. The storage pads 160 may include at least one of, for example, an impurity-doped semiconductor material, a conductive silicide compound, a conductive metal nitride, a conductive metal carbide, a metal, and a metal alloy.

Storage pad spacers 160SP may be positioned on the storage contacts 120. The storage pad spacers 160SP may be disposed between the storage pads 160 and the bitline structures 140ST, as well as between the storage patterns 160 and the fence patterns 170. Unlike what is depicted, the storage pad spacers 160SP may be omitted. The storage pad spacers 160SP may include at least one of, for example, SiO₂, SiN, SiON, SiOCN, and SiCN.

Pad separation insulating films 180 may be formed on the storage pads 160 and the bitline structures 140ST. For example, the pad separation insulating films 180 may be disposed on the cell line capping films 144. The pad separation insulating films 180 may define portions of the storage pads 160 that form multiple isolation regions. The pad separation insulating films 180 may not cover the top surfaces of the storage pads 160.

The pad separation insulating films 180 may include an insulating material to electrically isolate the storage pads 160 from one another. The pad separation insulating films 180 may include at least one of, for example, SiO₂, SiN, SiON, SiOCN, and SiCN.

First etch stop films 292 may be disposed on the pad separation insulating films 180 and the storage pads 160. The first etch stop films 292 may extend not only over the cell region 20 but also over the peripheral region 24. The first etch stop films 292 may include at least one of SiN, SiC, silicon boron nitride (SiBN), SiON, and SiOCN.

The data storage section 190 may be disposed on the storage pads 160. The data storage section 190 may be electrically connected to the storage pads 160. Some portions of the data storage section 190 may be positioned within the first etch stop films 292. The data storage section 190 may include, for example, capacitors, but the present disclosure is not limited thereto. The data storage section 190 may include first lower electrodes 191, a first capacitor dielectric film 192, and a first upper electrode 193.

The first lower electrodes 191 may be disposed on the storage pads 160. The first lower electrodes 191 are illustrated as having a pillar shape, but the present disclosure is not limited thereto. Alternatively, the first lower electrodes 191 may have a cylindrical shape. The first capacitor dielectric film 192 is formed on the first lower electrode 191. The first capacitor dielectric film 192 may be formed along the profiles of the first lower electrodes 191. The first upper electrode 193 is formed on the first capacitor dielectric film 192. The first upper electrode 193 may surround the outer sidewalls of the first lower electrodes 191.

For example, the first capacitor dielectric film 192 may be disposed in portions that vertically overlaps with the first upper electrode 193. Alternatively, contrary to what is depicted, the first capacitor dielectric film 192 may include first portions that vertically overlap with the first upper electrode 193 and second portions that do not vertically overlap with the first upper electrode 193. In other words, the second portions of the first capacitor dielectric film 192 are portions of the first capacitor dielectric film 192 that are not covered by the first upper electrode 193.

The first lower electrodes 191 and the first upper electrode 193 may include at least one of, for example, a doped semiconductor material, a conductive metal nitride (such as titanium nitride, tantalum nitride, niobium nitride, or tungsten nitride), a metal (such as cesium, iridium, titanium, or tantalum), and a conductive metal oxide (such as iridium oxide or niobium oxide), but the present disclosure is not limited thereto.

The first capacitor dielectric film 192 may include, for example, silicon oxide, silicon nitride, silicon oxynitride, a high-k constant material, and a combination thereof, but the present disclosure is not limited thereto. The first capacitor dielectric film 192 may include a stacked layer structure obtained by sequentially stacking zirconium oxide, aluminum oxide, and zirconium oxide. The first capacitor dielectric film 192 may include a dielectric layer containing hafnium (Hf). The first capacitor dielectric film 192 may have a stacked layer structure consisting of a ferroelectric material film and a paraelectric material film.

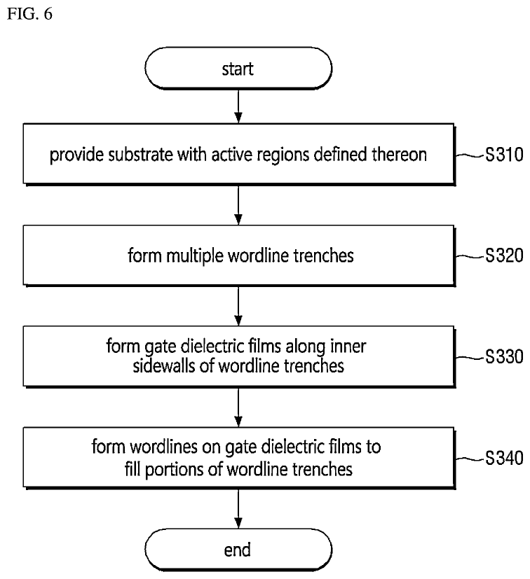

The formation of wordlines as performed in a method of fabricating a semiconductor device according to some embodiments of the present disclosure will hereinafter be described with reference to FIGS. 6 through 14.

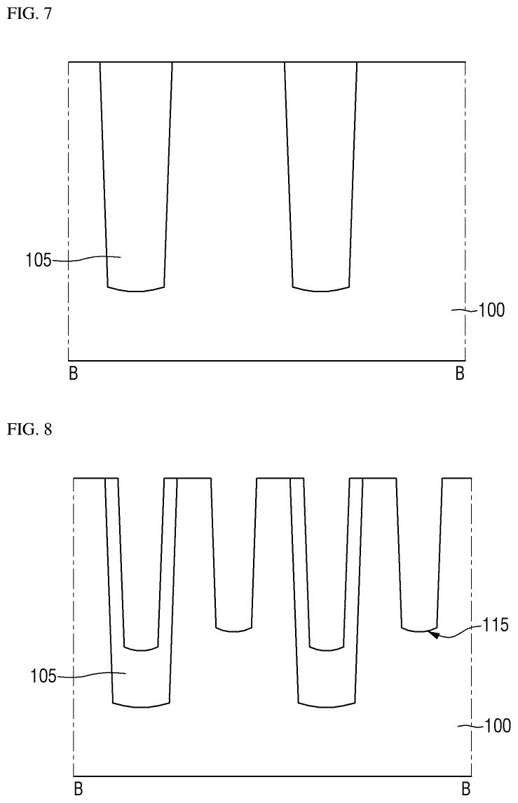

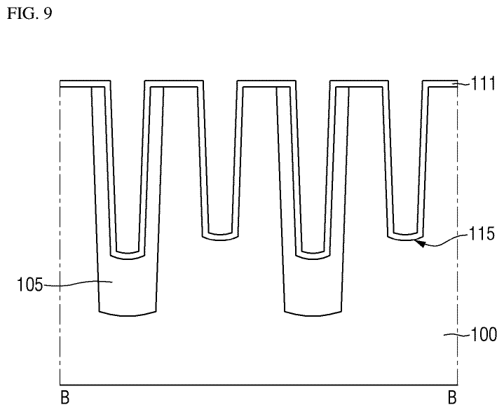

FIG. 6 is a flowchart illustrating a method of fabricating a semiconductor device according to some embodiments of the present disclosure. FIG. 7 is a cross-sectional view illustrating S310 of FIG. 6. FIG. 8 is a cross-sectional view illustrating S320 of FIG. 6. FIG. 9 is a cross-sectional view illustrating S330 of FIG. 6.

Referring to FIGS. 6 and 7, a substrate 100 where a plurality of active regions (“ACT” of FIGS. 2 and 3), which are spaced apart from one another by a device isolation film 105, are defined is provided (S310).

Thereafter, referring to FIGS. 6 and 8, a plurality of wordline trenches (or gate trenches) 115, which extend longitudinally in one direction, are formed (S320) by removing portions of the active regions ACT and portions of the device isolation film 105 using a mask.

As illustrated in FIG. 8, the depth of the wordline trenches 115 formed in the active regions ACT may differ from the depth of the wordline trenches 115 formed within the device isolation film 105. That is, the depth of the wordline trenches 115 formed within the device isolation film 105 may be greater than the depth of the wordline trenches 115 formed in the active regions ACT. The difference between the depth of the wordline trenches 115 formed within the device isolation film 105 and the depth of the wordline trenches 115 formed in the active regions ACT vary depending on the recipe/etchant/ions used in an etching method for forming the wordline trenches 115. In the example of FIG. 8, in the etching method for forming the wordline trenches 115, the etch rate of the device isolation film 105 is greater than the etch rate of the substrate 100 (particularly, the active regions ACT).

Thereafter, referring to FIGS. 6 and 9, gate insulating films 111 are formed along the inner sidewalls of the wordline trenches 115 (S330). That is, the gate insulating films 111 may extend along the sidewalls and bottom surfaces of the wordline trenches 115 and may also be formed on the top surface of the substrate 100.

Thereafter, referring to FIG. 6, wordlines 112, which fill portions of the wordline trenches 115, are formed on the gate insulating films 111 (S340).

As previously mentioned, the wordlines 112 may include at least one of a metal, a metal alloy, a conductive metal nitride, a conductive metal carbonitride, a conductive metal carbide, a metal silicide, a conductive metal oxynitride, and a conductive metal oxide. The formation of the wordlines 112 encompasses filling portions of the wordline trenches 115 with a metal layer using, for example, the SFD method.

The wordline trenches 115 may have a width of, for example, 20 nm, particularly, 10 nm to 20 nm. When the wordline trenches 115 are narrow, the entrances of the wordline trenches 115 may become obstructed by a metal due to the zipper effect, and this may happen even if an atomic layer deposition (ALD) method is used to fill the wordline trenches 115 with the metal, but the interior of the wordline trenches 115 remains insufficiently filled. Consequently, the resistance of the wordlines 112 may increase. In contrast, in some embodiments, by forming the wordlines 112 using the SFD method that will be described later, the interior of the wordline trenches 115 can be adequately filled, leading to a reduction in the resistance of the wordlines 112. Additionally, the SFD method can expedite the formation of the wordlines 112 compared to the ALD method.

An apparatus and method for filling portions of the wordline trenches 115 with a metal layer will hereinafter be described with reference to FIGS. 10 through 13.

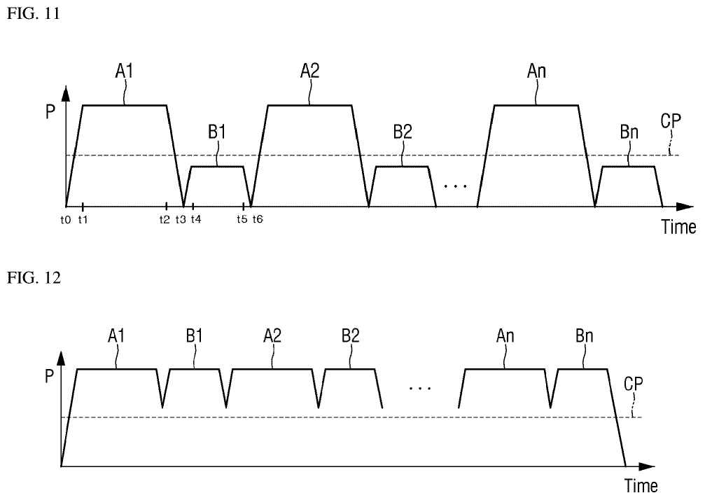

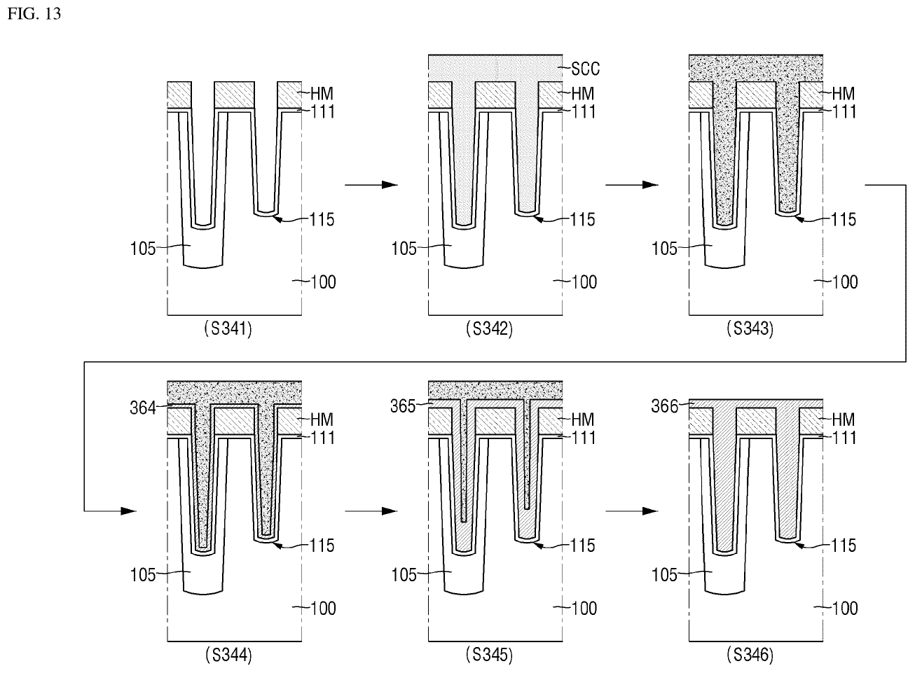

FIG. 10 is a schematic view illustrating semiconductor manufacturing equipment for performing S340 of FIG. 6. FIG. 11 is a schematic view illustrating an exemplary operating method of the semiconductor manufacturing equipment of FIG. 10. FIG. 12 is a schematic view illustrating another exemplary operating method of the semiconductor manufacturing equipment of FIG. 10. FIG. 13 illustrates cross-sectional views illustrating S340 of FIG. 6.

Referring to FIG. 10, the semiconductor manufacturing equipment may include a reactor 410, a support 412, a metal precursor supply unit 420, and a reduction gas supply unit 430.

The metal precursor supply unit 420 may provide a metal precursor and carbon dioxide. For example, the metal precursor may be in a dissolved state due to carbon dioxide. The metal precursor supply unit 420 may deliver the metal precursor and carbon dioxide in a supercritical state. Even if not supplied in a supercritical state, the metal precursor and carbon dioxide may be supplied into the reactor 410 for a predetermined period of time, increasing the pressure inside the reactor 410 and causing the metal precursor and carbon dioxide to attain a supercritical state within the reactor 410.

The composition of the metal precursor may vary depending on the type of the material used to fill the wordlines 112. The metal precursor is in an ML form (where M represents metal and L represents ligand). The metal M may include at least one of Ru, Mo, Cu, and TiN, but the present disclosure is not limited thereto. The ligand L consists only of carbon (C) and/or hydrogen (H). In other words, the ligand L may be composed of one of Cₓ, H_{y}, and CₓH_{y} (where x and y are natural numbers). The ligand L does not include F, Cl, or the like.

If the ligand L includes F, Cl, or the like, the ligand L may penetrate into the gate insulating films 111, leading to the formation of charge traps within the gate insulating films 111. On the other hand, if the ligand L consists only of C and/or H, charge traps are not formed within the gate insulating films 111.

The reduction gas supply unit 430 may provide a reduction gas and carbon dioxide. For example, the reduction gas may be in a dissolved state due to carbon dioxide. The reduction gas may include H₂ or NH₃, but the present disclosure is not limited thereto.

The reduction gas supply unit 430 may deliver the reduction gas and carbon dioxide in a supercritical state. Even if not supplied in a supercritical state, the reduction gas and carbon dioxide may be supplied into the reactor 410 for a predetermined period of time, increasing the pressure inside the reactor 410 and causing the reduction gas and carbon dioxide to attain a supercritical state within the reactor 410.

Here, referring to FIGS. 10 and 11, a substrate where the wordline trenches 115 are formed is placed within the reactor 410. Specifically, a substrate with the structure depicted in FIG. 9 is positioned on the substrate 412.

Thereafter, the metal precursor supply unit 420 supplies the metal precursor into the reactor 410 along with carbon dioxide (in step “A1” of FIG. 11).

Specifically, the metal precursor supply unit 420 starts supplying the metal precursor along with carbon dioxide into the reactor 410 at “t0”.

As the metal precursor and carbon dioxide are supplied into the reactor 410 for a predetermined period of time (i.e., a period between “t0” and “t1”), the pressure within the reactor 410 may reaches a critical pressure CP or higher. Then, the metal precursor may become supercritical. The metal precursor in a supercritical state may easily penetrate the spaces within the wordline trenches 115 with a high aspect ratio.

Between “t1” and a “t2,” the pressure within the reactor 410 is maintained within a predetermined range. For example, the pressure within the reactor 410 may be uniformly maintained. The thickness of metal layers deposited within the wordline trenches 115 may be controlled depending on the length (or duration) of the period between “t1” and “t2.” The longer the period between “t1” and “t2,” the greater the thickness of the metal layers.

During a period between “t2” and “t3,” the metal precursor and carbon dioxide are rapidly vented from the reactor 410.

Thereafter, the reduction gas supply unit 430 supplies the reduction gas into the reactor 410 along with carbon dioxide (in step “B1” of FIG. 11). Alternatively, the reduction gas supply unit 430 may provide only the reduction gas without carbon dioxide, depending on the recipe.

Specifically, the reduction gas and carbon dioxide are supplied for a predetermined period of time (i.e., between “t3” and “t4”). During a period between “t4” and “t5,” the pressure of the reduction gas and carbon dioxide within the reactor 410 is maintained within a predetermined range. For example, the pressure of the reduction gas and carbon dioxide may be uniformly maintained.

During a period between “t5” and “t6,” the reduction gas and carbon dioxide are rapidly vented from the reactor 410.

When the metal precursor is in the form of ML (where M is a metal and L is a ligand) and the reduction gas is H₂, the reduction gas and the metal precursor react, initiating the formation of metal layers, as shown in Chemical Equation (1):

ML₂+H₂→M+2HL.

In another example, when the metal precursor Ru(tmhd)₂cod and the reduction gas is H₂, the reaction proceeds as shown in Chemical Equation (2):

Ru(tmhd)₂cod+2H₂→Ru(s)+coe(g)+2(tmhd)H(g).

Steps “A1” and “B1” may be performed multiple times. As steps “A1” and “B1” are performed multiple times, the thickness of the metal layers formed may increase. Steps “A1” and “B1” may be performed a predetermined number of times. Referring to FIG. 11, steps “A1” and “B1” are repeated n times (where n is 3 or greater).

After step “B1,” the metal precursor supply unit 420 supplies the metal precursor into the reactor 410 along with carbon dioxide (in step “A2” of FIG. 11). Thereafter, the reduction gas supply unit 430 supplies the reduction gas into the reactor 410 along with carbon dioxide (in step “B2” of FIG. 11). Thereafter, the metal precursor supply unit 420 supplies the metal precursor into the reactor 410 along with carbon dioxide (in step “An” of FIG. 11). Thereafter, the reduction gas supply unit 430 supplies the reduction gas into the reactor 410 along with carbon dioxide (in step “Bn” of FIG. 11).

Although not explicitly illustrated, after step “Bn,” the reactor 410 may be rinsed using supercritical carbon dioxide. By utilizing supercritical carbon dioxide, any remaining metal precursor within the reactor 410 can be easily removed.

The operating method of FIG. 12 includes multiple repetitions of the supply of the metal precursor along with carbon dioxide and the supply of the reduction gas. In the operating method of FIG. 12, unlike in the operating method of FIG. 11, during the venting operation in each of steps “A1,” “A2,” and “An,” the internal pressure of the reactor 410 is maintained above the critical pressure CP. Similarly, during the venting operation in each of steps “B1” and “B2,” the pressure of the reactor 410 is maintained above the critical pressure CP. In this manner, during an SFD process within the reactor 410, the internal pressure of the reactor 410 can be prevented from dropping below the critical pressure CP.

The filling of the wordline trenches 115 with a metal will hereinafter be described with reference to FIG. 13.

Referring to FIG. 13, a substrate W with wordline trenches 115 formed therein is placed within the reactor 410 (S341).

Thereafter, a supercritical metal precursor SCC penetrates between the wordline trenches 115 within the reactor 410 (S342).

The supercritical metal precursor SCC possesses higher penetration ability, lower surface tension, and higher diffusivity than liquid. On the other hand, the supercritical metal precursor SCC has higher density and solubility than gas. Due to these characteristics, the use of the supercritical metal precursor SCC enables faster deposition compared to ALD. Furthermore, the use of the supercritical metal precursor SCC exhibits better step coverage than chemical vapor deposition (CVD) and minimizes the risks of defects and contamination.

Thereafter, a reduction gas is supplied into the reactor 410 (S343).

Thereafter, a reaction between the supercritical metal precursor SCC and the reduction gas initiates the formation of thin metal layers 364 within the wordline trenches 115 (S344).

Thereafter, as mentioned earlier, as the supply of the supercritical metal precursor SCC and the supply of the reduction gas are repeated multiple times, the thin metal layers 364 may be thickened into metal layers 365 (S345).

Thereafter, the wordline trenches 115 are completely filled with metal layers 366. The metal layers 366 may be formed even on the top surfaces of the wordline trenches 115 (S346). The metal layers 366 may also be referred to as pre-metal layers 366.

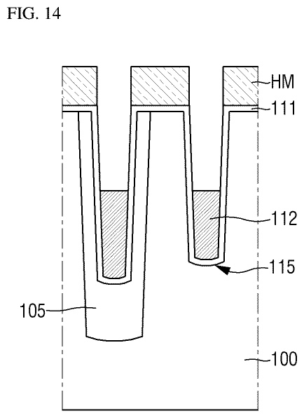

Referring to FIG. 14, the pre-metal layers 366 are partially removed using atomic layer etching (ALE), thereby forming metal layers (or wordlines) 112, which fill portions of the wordline trenches 115.

Referring to FIG. 5, after the formation of the wordlines 112, capping conductive films 114 are formed on the wordlines 112 within the wordline trenches 115. The capping conductive films 114 may include polysilicon or polysilicon germanium, but the present disclosure is not limited thereto.

After the formation of the capping conductive films 114, capping insulating films 113 are formed on the capping conductive films 114 within the wordline trenches 115. The capping insulating films 113 may include at least one of SiN, SiON, SiO₂, SiCN, SiOCN, and a combination thereof.

Meanwhile, as described above with reference to FIG. 1, a cell region 20 and a peripheral region 24 are defined on the substrate W. Not only first transistors formed in the cell region 20, but also second transistors formed in the peripheral region 24 may be buried channel array transistors (BCATs).

Therefore, not only the gate electrodes of the first transistors, but also the gate electrodes of the second transistors can be formed by the SFD method.

Specifically, the first transistors and the second transistors may be formed by forming first trenches in the cell region 20 and second trenches in the peripheral region 24, forming first gate insulating films along the inner sidewalls of the first trenches and second gate insulating films on the inner sidewalls of the second trenches, and forming first metal layers on the first gate insulating films and second metal layers on the second gate insulating films using the SFD method to fill portions of the first trenches with the first metal layers and portions of the second trenches with the second metal layers.

Here, the filling of portions of the first trenches with the first metal layers using the SFD method involves placing the substrate W within the reactor 410, supplying the reactor 410 with a metal precursor and carbon dioxide to enable penetration of the metal precursor into the first trenches, and introducing a reduction gas into the reactor 410 such that the metal of the metal precursor can be deposited within the first trenches.

Similarly, the filling of portions of the second trenches with the second metal layers using the SFD method involves placing the substrate W within the reactor 410, supplying the reactor 410 with the metal precursor and carbon dioxide to enable penetration of the metal precursor into the second trenches, and introducing the reduction gas into the reactor 410 such that the metal of the metal precursor metal can be deposited within the second trenches.

The ligand of the metal precursor does not contain F or Cl, but consists solely of C and/or H (i.e., Cₓ, H_{y}, or CₓH_{y} where x and y are natural numbers). The absence of F and Cl in the ligand of the metal precursor prevents the occurrence of charge traps within the first gate insulating films and the second gate insulating films.

Embodiments of the present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

What is claimed is:

1. A method of fabricating a semiconductor device, comprising:
providing a substrate having defined thereon a plurality of active regions, which are spaced apart from one another by a device isolation film;
forming a plurality of wordline trenches, which extend longitudinally in one direction, by removing portions of the active regions and portions of the device isolation film;
forming gate insulating films along inner sidewalls of the wordline trenches; and
forming wordlines, which fill portions of the wordline trenches, on the gate insulating films,
wherein the forming the wordlines, comprises filling the portions of the wordline trenches with metal layers using a supercritical fluid deposition (SFD) method.

2. The method of claim 1, wherein
the filling the portions of the wordline trenches using the SFD method, comprises placing the substrate with the wordline trenches formed therein within a reactor, supplying a metal precursor and carbon dioxide into the reactor such that the metal precursor penetrates into the wordline trenches, and supplying a reduction gas into the reactor such that a metal of the metal precursor is deposited within the wordline trenches, and
the metal precursor and the carbon dioxide are in a supercritical state within the reactor.

3. The method of claim 2, wherein the reduction gas is in a supercritical state within the reactor.

4. The method of claim 2, wherein a ligand of the metal precursor consists of one of Cₓ, H_{y}, and CₓH_{y} (where x and y are natural numbers).

5. The method of claim 2, wherein the metal layers include at least one of Ru, Mo, Cu, and TiN.

6. The method of claim 2, wherein the reduction gas includes H₂ or NH₃.

7. The method of claim 2, wherein the filling the portions of the wordline trenches using the SFD method, further comprises repeating both the supplying the metal precursor and the carbon dioxide into the reactor and the supplying the reduction gas into the reactor multiple times.

8. The method of claim 7, wherein the filling the portions of the wordline trenches using the SFD method, further comprises rinsing the interior of the reactor with supercritical carbon dioxide after the repeating both the supplying the metal precursor and the carbon dioxide into the reactor and the supplying the reduction gas into the reactor multiple times.

9. The method of claim 1, wherein the forming the wordlines, comprises forming pre-metal layers, which completely fill the wordline trenches, using the SFD method, and forming metal layers, which fill the portions of the wordline trenches, by removing portions of the pre-metal layers using an atomic layer etching (ALE) method.

10. The method of claim 1, further comprising:
forming capping conductive films on the wordlines within the wordline trenches after the forming the wordlines.

11. The method of claim 10, further comprising:
forming capping insulating films on the capping conductive films within the wordline trenches after the forming the capping conductive films.

12. The method of claim 1, wherein the wordline trenches have a width of 20 nm or less.

13. A method of fabricating a semiconductor device, comprising:
providing a substrate having defined thereon a plurality of active regions, which are spaced apart from one another by a device isolation film;
forming a plurality of wordline trenches, which extend longitudinally in one direction, by removing portions of the active regions and portions of the device isolation film;
forming gate insulating films along inner sidewalls of the wordline trenches; and
forming wordlines, which fill portions of the wordline trenches, on the gate insulating films,
wherein
the forming the wordlines, comprises placing the substrate with the wordline trenches formed therein within a reactor, supplying a metal precursor and carbon dioxide into the reactor such that the metal precursor penetrates into the wordline trenches, and supplying a reduction gas into the reactor such that a metal of the metal precursor is deposited within the wordline trenches,
the metal precursor and the carbon dioxide are in a supercritical state within the reactor,
the metal of the metal precursor is at least one of Ru, Mo, Cu, and TiN,
a ligand of the metal precursor consists of one of Cₓ, H_{y}, and CₓH_{y} (where x and y are natural numbers),
the reduction gas is in a supercritical state within the reactor, and
the forming the wordlines, comprises forming pre-metal layers, which completely fill the wordline trenches, by repeating both the supplying the metal precursor and the carbon dioxide into the reactor and the supplying the reduction gas into the reactor multiple times, and forming metal layers, which fill the portions of the wordline trenches, by removing portions of the pre-metal layers using an atomic layer etching (ALE) method.

14. The method of claim 13, further comprising:
forming capping conductive films on the wordlines within the wordline trenches after the forming the wordlines.

15. The method of claim 14, further comprising:
forming capping insulating films on the capping conductive films within the wordline trenches after the forming the capping conductive films.

16. A method of fabricating a semiconductor device, comprising:
providing a substrate, which includes a cell region and a peripheral region defined around the cell region; and
forming first transistors in the cell region and second transistors in the peripheral region, the first transistors and the second transistors being buried channel array transistors (BCATs),
wherein the forming the first transistors and the second transistors, comprises forming first trenches in the cell region and second trenches in the peripheral region, forming first gate insulating films along inner sidewalls of the first trenches and second gate insulating films along inner sidewalls of the second trenches, and filling portions of the first trenches with first metal layers and portions of the second trenches with second metal layers by forming the first metal layers on the first gate insulating films and the second metal layers on the second gate insulating films using a supercritical fluid deposition (SFD) method.

17. The method of claim 16, wherein the filling the portions of the first trenches with the first metal layers using the SFD method, comprises placing the substrate within a reactor, supplying a metal precursor and carbon dioxide into the reactor such that the metal precursor penetrates into the first trenches, and supplying a reduction gas into the reactor such that a metal of the metal precursor is deposited within the first trenches.

18. The method of claim 17, wherein a ligand of the metal precursor consists of one of Cₓ, H_{y}, and CₓH_{y} (where x and y are natural numbers).

19. The method of claim 16, further comprising, after the forming the wordlines:
forming capping conductive films on the wordlines within the wordline trenches; and
forming capping insulating films on the capping conductive films within the wordline trenches.
